(19) United States
(12) Patent Application Publication
(10) Pub. No.: US 2010/0029026 A1
(43) Pub. Date: Feb. 4, 2010

(54) METHOD OF FABRICATING AN OPTICAL ANALYSIS DEVICE COMPRISING A QUANTUM CASCADE LASER AND A QUANTUM DETECTOR

(75) Inventors: Vincent Berger, Ivry (FR); Mathieu Carras, Gentilly (FR)

Correspondence Address: LARIVIERE, GRUBMAN & PAYNE, LLP, 19 UPPER RAGSDALE DRIVE, SUITE 200, MONTEREY, CA, 93940, US

(73) Assignee: Thales, Neuilly Sur Seine (FR)

(21) Appl. No.: 12/533,429

(22) Filed: Jul. 31, 2009

(30) Foreign Application Priority Data
Aug. 1, 2008 (FR) 08 04413

(51) Int. Cl. H01L 21/00

(52) U.S. Cl. 438/24; 257/E21.001

(57) ABSTRACT

The invention relates to a method of fabricating an optical device for analysing a scene, comprising an emitter and a detector in the mid-infrared or far-infrared, characterized in that it comprises:
the production of a stack of semiconductor layers grown epitaxially on the surface of a semiconductor substrate, certain layers of which are doped;
the production of a first, quantum cascade laser emission device (L) emitting an analysis beam in the mid-infrared or far-infrared, from a first level called the emission level, into the stack of semiconductor layers; and
the production of a second, quantum detector device (D) capable of detecting a beam backscattered by the scene to be analysed, at the same level in the stack as the emission level.

### PRIORITY CLAIM

This application claims priority to French Patent Application Number 08 04413, entitled Method Of Fabricating An Optical Analysis Device Comprising A Quantum Cascade Laser And A Quantum Detector, filed on Aug. 1, 2008.

### TECHNICAL FIELD

The field of the invention is that of spectroscopic mid-infrared or far-infrared remote detection devices.

### BACKGROUND ART

Currently, there are optical systems for detecting particular molecular entities present in a given environment, for example gas molecules, used for process control, environment control or medical analysis, which employ a laser and a detector.

Notably, there are backscattering devices, usually called LIDAR (Light Detection And Ranging) devices, which represent key systems in determining the spatial distribution and optical properties of aerosols and clouds. Such information is fundamental in many meteorological and environmental applications in the laboratory or in the field.

In said systems, the laser may be in the visible, the near-infrared or the mid-infrared. The light emitted passes through the gas to be analysed, possibly in a resonant cavity, and the detector analyses the transmitted light. A distinction may be made between photoacoustic detection and detection of the light directly attenuated by the gas. In both cases, the laser and the detector are separate devices produced in different technologies.

A major drawback of these detection systems is that they are formed from an assembly of components (laser, cavity or mirrors, detector) that are relatively complex to fabricate, assemble and implement.

Easier robustness and implementation are achieved using certain hybrid solutions. For example, photoacoustic detection does not require an optical detector, but simply a microphone.

However, this solution remains an assembly of components and limits the functionalities (no imaging is possible).

### DISCLOSURE OF INVENTION

This is why, within this context, the present invention proposes to integrate the detector and the laser source into a monolithic device during design of the component.

More precisely, one subject of the invention is a method of fabricating an optical device for analysing a scene, comprising an emitter and a detector in the mid-infrared or far-infrared, characterized in that it comprises:
the production of a stack of semiconductor layers grown epitaxially on the surface of a semiconductor substrate, certain layers of which are doped;
the production of a first, quantum cascade laser emission device (QCL) emitting an analysis beam in the mid-infrared or far-infrared, from a first level called the emission level, into the stack of semiconductor layers; and
the production of a second, quantum detector device capable of detecting a beam backscattered by the scene to be analysed, at the same level in the stack as the emission level.

According to one embodiment of the invention, the analysis beam is directed towards the scene.

According to one embodiment of the invention, the method further includes the production of a local oscillator device for performing a heterodyne detection.

According to one embodiment of the invention, the analysis beam is partly directed towards the scene and partly directed towards the detector.

According to one embodiment of the invention, the analysis beam is directed towards the detection device, the heterodyne detection being performed by interference between an analysis optical signal and an optical signal generated by the scene to be analysed.

According to one embodiment of the invention, the first and second devices are produced within a single stack of layers by an etching operation within said stack of semiconductor layers.

According to one embodiment of the invention, the first and second devices are produced at the same location in the stack of semiconductor layers and are activated in succession by specific control means.

According to one embodiment of the invention, the method further includes the production of a diffracting device coupling onto the quantum cascade laser for making the light exit at normal incidence to the plane of the semiconductor layers.

According to one embodiment of the invention, the method further includes the production of a diffracting device coupling onto the quantum detector for coupling the light at normal incidence to the plane of the semiconductor layers.

According to one embodiment of the invention, the optical device obtained by the method is intended for analysing gaseous species.

Another subject of the invention is a method of fabricating an imaging system, comprising the production of a matrix of optical analysis devices according to the invention, distributed in a matrix arrangement on the surface of a semiconductor substrate.

Yet another subject of the invention is a method of fabricating a multispectral analysis system, comprising the production of a number of optical analysis devices according to the invention and characterized in that each device emits at a specific wavelength.

According to one embodiment of the invention, the variation in specific wavelength is obtained by varying the characteristics of each emission device.

### BRIEF DESCRIPTION OF THE DRAWINGS

The invention will be better understood and other advantages will become apparent on reading the following description given by way of non-limiting example and examining the appended figures, in which:

FIGS. 1a to 1f show schematically a number of possible optical analysis device configurations obtained according to the method of the invention;

FIG. 2 illustrates a first example of an optical analysis device obtained according to the method of the invention, in which the emitter and detector devices are spatially separate;

FIG. 3 illustrates a second example of an optical analysis device obtained according to the method of the invention, in which the emitter and detector devices are provided in one and the same location;

FIG. 4 illustrates a third example of the invention, in which a local oscillator is produced so as to be integrated into the emission device, for heterodyne detection; and

FIG. 5 illustrates a fourth example of an optical analysis device obtained according to the method of the invention and comprising a laser separate from the emission device for heterodyne detection.

### DETAILED DESCRIPTION AND BEST MODES FOR CARRYING OUT THE INVENTION

The invention will be described within the context of detecting gas molecules, but it could equally well apply both to the detection of other types of molecular species in a given medium or the analysis of any type of surface or scene, from which it is desired to extract information using a beam backscattered by said scene.

In general, the fabrication method of the invention makes it possible to produce an integrated device which is simple and robust compared with the current systems and is based on a well-established understanding of controlling the epitaxial growth of Ill-V materials.

The method consists of using the technological process for such growth in order to produce an integrated LIDAR system comprising at least one emitter and at least one detector integrated into one and the same component.

The method of fabricating the detection device according to the invention makes it possible to produce, on a single semiconductor substrate, a structure such that it operates both as a quantum cascade laser QCL and as a quantum detector, which advantageously may be a quantum cascade detector QCD.

According to the invention, the method also may be used to create a local oscillator function within the stack.

Specifically, to increase the sensitivity of the device, the detector may be used in heterodyne mode, making it possible for signal/noise problems to be greatly reduced. In this case, a quantum cascade laser serves as local oscillator called LO illuminating the detector according to the principles of heterodyne detection described in the literature.

In general, in a heterodyne system, the incident signal of frequency fₛ and the reference signal of frequency f₀ (coming from a local oscillator) are mixed in a non-linear element (a mixer). These signals of close frequencies are recovered at the output of a mixer at a lower frequency, called intermediate frequency, which can be more easily amplified than the starting high frequencies. Spectrum analysers are then capable of analysing the frequency-lowered signal with very great precision in terms of amplitude and frequency.

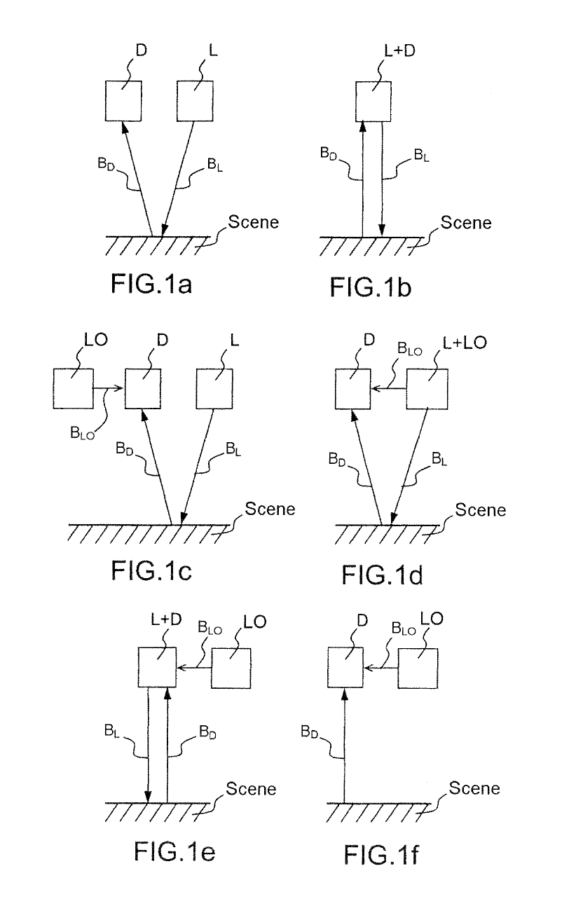

The set of FIGS. 1a to 1f illustrate various possible configurations describing a number of emission and detection devices produced in the stack of semiconductor layers.

The diagram shown in FIG. 1a relates to a configuration in which the emission device L and the detection device D are produced separately within the stack of semiconductor layers, the analysis beam B_{L} being sent directly towards the scene to be analysed and the detector detecting a beam B_{D} backscattered by said scene.

The diagram shown in FIG. 1b relates to a configuration in which the emission and detection devices are produced in the same location of the stack and are activated by appropriate control means.

The diagram shown in FIG. 1c relates to a configuration comprising a local oscillator LO, an ancillary emission source which sends an optical beam B_{LO} into the detector so as to make the beam B_{D} coming from the scene interfere with the beam B_{LO}.

The diagram shown in FIG. 1d relates to a configuration in which the same location in the stack of semiconductor layers is used to create the emission device and the local oscillator device. Thus, one part of the emission B_{L} is sent towards the scene and another part of the emission B_{LO} is sent into the detector.

The diagram shown in FIG. 1e relates to a configuration in which a local oscillator LO is an ancillary source delivering an optical beam B_{LO} towards the emission device L and the detection device D which are produced at the same location in the stack and are activated by appropriate control means.

The diagram shown in FIG. 1f relates to a configuration in which the emission device acts as local oscillator and emits an optical beam B_{LO} towards the detector D, the heterodyne detection being performed by interference between the optical beam B_{LO} and the optical signal B_{L} coming directly from the scene to be analysed.

In general and according to the method of the invention, a stack of semiconductor layers is produced.

To do this, the aim is to grow, on a semiconductor substrate which may itself provide an electrode function or may be covered with a layer providing this function, a stack of semiconductor layers, certain of which are doped for obtaining the desired functions.

Typically, the stack comprises a bottom confinement layer, a gain region, a top confinement layer and a top electrode.

More precisely, the quantum cascade laser comprises two electrodes for applying a control electric field, a waveguide placed between the electrodes, and a structure comprising a gain region formed from a multilayer that comprises an alternation of layers of a first type each defining a quantum barrier and layers of a second type each defining a quantum well, these layers being made from first and second semiconductor materials constituting barriers and wells respectively.

The structure further includes two optical confinement layers placed on either side of the gain region. The upper surface of the top confinement region may form an optical grating intended for selecting a predetermined wavelength within the band of wavelengths emitted in the gain region. This type of laser is called a DFB (distributed feedback) laser and is used notably in applications in the field of gas absorption spectroscopy.

The constituent materials of the barriers and wells are chosen so that they have a crystal lattice matched to that of the substrate in order to maintain the single-crystal structure throughout the thickness of the laser.

The gain region itself consists of a multilayer constituting quantum wells and quantum barriers, and forming a zone in which inter-sub-band electronic transitions can take place.

More precisely, the electrons travelling from one electrode to the other pass from one sub-band to another sub-band in the gain region, emitting photons, according to a process known from the literature, thereby constituting the emission laser capable of emitting an incident beam for analysing given gaseous species.

To detect gaseous species having an absorption line in a frequency range centred on a frequency ω_{gas}, structure parameters are chosen such that they enable the quantum cascade laser to generate pulses with a frequency lying within a frequency range [ω₁; ω₂] that includes the frequency ω_{gas}, when a suitable electric field is applied.

The analysis of a gas requires that the wavelength of the detector be precisely defined. This is why, according to the invention, a DFB quantum cascade detector technology is particularly well suited for providing the detection function.

In this case, the wavelength of the QCL is tuned to an absorption line of the gas to be analysed, and this wavelength may undergo a variation over an electrical supply pulse duration of the QCL so as to spectrally cover the absorption line of the gas, according to a principle known in the literature.

A geometry of the external cavity type may also be used for the QCL according to a principle known from the literature.

In general, the stack of layers is produced by conventional epitaxy processes: MOCVD, MBE, etc.

The emission devices thus produced emit in wavelength ranges of around 1 to 300 microns, i.e. all wavelengths accessible by the QCLs.

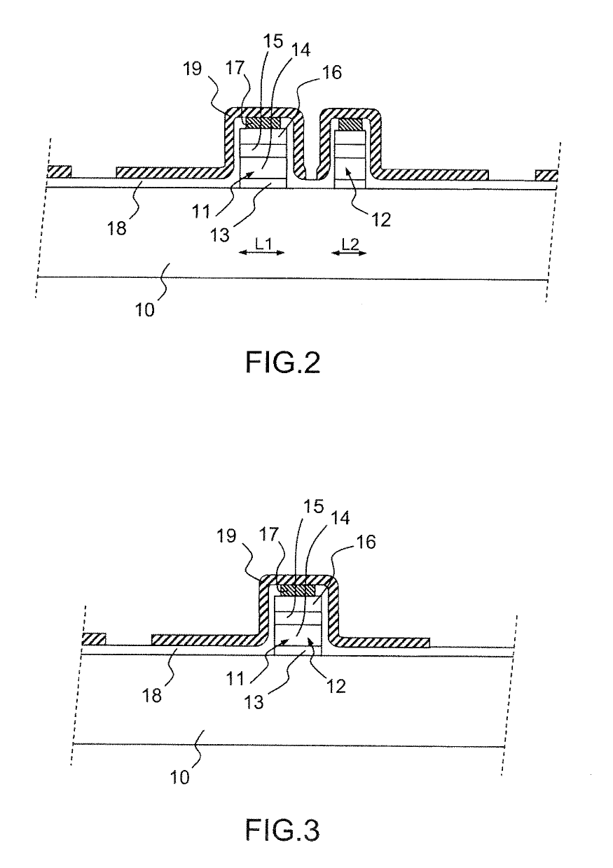

In one embodiment of the invention, the laser and the detector are two components produced from the same stack of epitaxially grown layers. They are physically separated spatially by an etching operation as illustrated in FIG. 2. More precisely, the two devices—emission device 11 and detection device 12—are produced on the surface of a semiconductor substrate 10 with a width L1 and L2 respectively (typically L1 may be between 5 and 30 μm and L2 may be around a few tens of microns up to 1 mm).

These stacks of semiconductor layers each comprise, from the substrate 10, a bottom confinement layer 13, a gain region 14, a top confinement layer 15 and a top electrode 16. The top electrode 16 is covered with a metal contact layer 17. Advantageously, a passivation layer 18 is provided for avoiding any short circuit between the top and bottom electrodes. A metal contact layer 19 may also be provided, intended for bonding electrical wires.

According to another embodiment of the invention, the laser and the detector are produced spatially at the same location in the stack, the two types of functions—emission and detection—being obtained sequentially by voltage control, as illustrated in FIG. 3. The structures 11 and 12 are produced within the same location.

It may be advantageous to make the light exit at normal incidence to the plane of the semiconductor layers, using a diffracting device coupling onto the QCL.

Various devices thus formed and defined by a QCL structure, a QCD structure and a local oscillator LO may be assembled so as to form a matrix of LIDARs. The whole assembly thus makes it possible to produce an imaging system and/or a multispectral analysis system.

In the imaging case, each elementary device analyses one direction in space using an optical coupling system.

In the multispectral analysis case, each device emits at one specific wavelength. This may be

obtained by varying the period of the DFB structure from one device to another during production of the QCL.

Since the overall size of a device may be less than 1 millimetre, matrix systems containing a large number of devices may be produced on the same substrate.

Optionally, the same QCL structure may serve at the same time as laser source and as local oscillator, as illustrated in FIG. 3.

For example, the laser radiation output from one face of a stripe produced by etching the stack of semiconductor layers of the QCL serves as probe beam to the outside and the laser radiation output from the other face of the QCL acts as local oscillator illuminating the QCD.

During a current pulse, the wavelength of the QCL varies because of the diode heating, this wavelength being denoted by λ(t). The wavelength that illuminates the QCD is λ(t) and the radiation from the QCL, which has probed the external space to be analysed and is reflected onto the detector at the same instant, has a wavelength λ(t−dt), where dt is the time interval for the light to go from the component, into the external space to be analysed and back to the component. The wavelength shift between λ(t) and λ(t+dt) makes it possible, by heterodyne detection, to measure the delay dt and therefore to perform a LIDAR-type analysis.

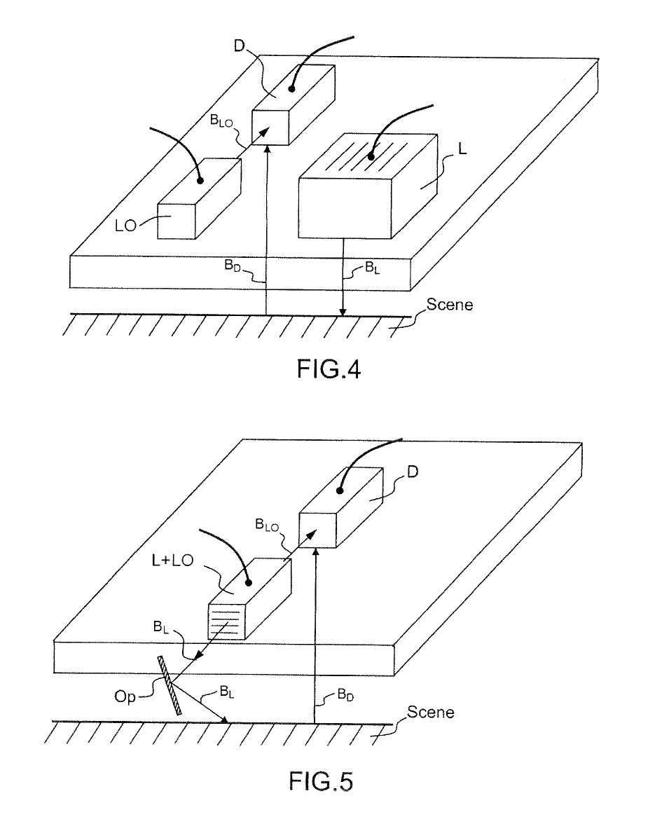

It is also quite possible according to the method of carrying out the invention to separate, within the stack of semiconductor layers, the emission device, the detection device and the local oscillator device, as shown in FIG. 4.

The emission device L emits an analysis beam towards the scene and the local oscillator emits an ancillary beam B_{LO} towards the detector in a direction parallel to the plane of the stack.

The optical signal B_{D} from the scene, and corresponding to the backscattered beam coming from the analysis beam B_{L}, interferes with said beam B_{LO}.

According to another embodiment of the invention, it is also possible for the emission of the laser device and the emission of the local oscillator to take place simultaneously from the same mesa in the stack of semiconductor layers, as illustrated in FIG. 5. The two opposed faces are thus dedicated to the two types of emission and make it possible to emit the beams B_{L} and B_{LO}. An optical system Op is used to convey the beam dedicated to emission towards the scene to be analysed so as to be able to make the beam B_{D} arising from B_{L} interfere with the beam B_{LO} at the detector D.

We claim:

1. A method of fabricating an optical device for analysing a scene, comprising an emitter and a detector in the mid-infrared or far-infrared, characterized in that it comprises:
the production of a stack of semiconductor layers grown epitaxially on the surface of a semiconductor substrate, certain layers of which are doped;
the production of a first, quantum cascade laser emission device (L) emitting an analysis beam in the mid-infrared or far-infrared, from a first level called the emission level, into the stack of semiconductor layers; and
the production of a second, quantum detector device (D) capable of detecting a beam backscattered by the scene to be analysed, at the same level in the stack as the emission level.

2. Method of fabricating an optical analysis device according to claim 1, wherein the analysis beam is directed towards the scene.

3. Method of fabricating an optical analysis device according to either of claims 1 or 2, including the production of a third, local oscillator device (LO) for performing a heterodyne detection.

4. Method of fabricating an optical analysis device according to claim 3, wherein the analysis beam is partly directed towards the scene and partly directed towards the detector.

5. Method of fabricating an optical analysis device according to claim 3, wherein the analysis beam is directed towards the detection device, the heterodyne detection being performed by interference between the analysis beam and a beam generated by the scene to be analysed.

6. Method of fabricating an optical analysis device according to claims 1 or 2, wherein the first and second devices are produced within a single stack of layers by an etching operation within said stack of semiconductor layers.

7. Method of fabricating an optical analysis device according to claims 1 or 2, wherein the first and second devices are produced at the same location in the stack of semiconductor layers and are activated in succession by specific control means.

8. Method of fabricating an optical analysis device according to claims 1 or 2, including the production of a diffracting device coupling onto the quantum cascade laser for making the light exit at normal incidence to the plane of the semiconductor layers.

9. Method of fabricating an optical analysis device according to claims 1 or 2, including the production of a diffracting device coupling onto the quantum detector for coupling the light at normal incidence to the plane of the semiconductor layers.

10. Method of fabricating an optical analysis device according to claims 1 or 2, wherein the optical device is intended for analysing gaseous species.

11. Method of fabricating an imaging system, comprising the production of a matrix of optical analysis devices according to claims 1 or 2, distributed in a matrix arrangement on the surface of a semiconductor substrate.

12. Method of fabricating a multispectral analysis system, comprising the production of a number of optical analysis devices according to claims 1 or 2 and wherein each device emits at a specific wavelength.

13. Method of fabricating a multispectral analysis system according to claim 12, wherein the variation in specific wavelength is obtained by varying the characteristics of each emission device.
